(19) United States
(12) Patent Application Publication
(10) Pub. No.: US 2025/0185302 A1
(43) Pub. Date: Jun. 5, 2025

(54) ARRAY SUBSTRATE, MANUFACTURING METHOD THEREOF AND DISPLAY PANEL

(71) Applicant: WUHAN CHINA STAR OPTOELECTRONICS SEMICONDUCTOR DISPLAY TECHNOLOGY CO., LTD., Wuhan, Hubei (CN)

(72) Inventors: Haiyan SHEN, Wuhan, Hubei (CN); Can HUANG, Wuhan, Hubei (CN); Wenxu XIANYU, Wuhan, Hubei (CN); Chunpeng ZHANG, Wuhan, Hubei (CN)

(21) Appl. No.: 17/596,868

(22) PCT Filed: Dec. 8, 2021
(86) PCT No.: PCT/CN2021/136549

§ 371 Date: Nov. 21, 2024

(30) Foreign Application Priority Data
Nov. 30, 2021 (CN) 202111445690.8

(51) Int. Cl. H10D 30/67; H10D 64/27; H10D 86/01; H10D 86/40; H10D 86/60

(52) U.S. Cl. CPC H10D 30/6736; H10D 64/516; H10D 64/518; H10D 64/519; H10D 86/021; H10D 86/60; H10D 86/423

(57) ABSTRACT

An array substrate, a manufacturing method thereof, and a display panel are provided. The array substrate includes an electrode layer, a gate insulating layer and an active layer. The electrode layer includes a first metal layer, a second metal layer, and a third metal layer that are stacked; a first end of the active layer is electrically connected to the first metal layer, and a second end of the active layer is electrically connected to the third metal layer; in a direction from the first metal layer to the third metal layer, the second metal layer includes at least two metal sub-layers which are stacked, and adjacent ones of the metal sub-layers are insulated from each other. By adjusting thicknesses and a number of the metal sub-layers, a width-to-length ratio of the channel of the active layer can be adjusted to flexibly adjust characteristics of the thin film transistor.

### FIELD OF INVENTION

The present invention relates to the field of display technology, in particular to an array substrate, a manufacturing method thereof, and a display panel.

### BACKGROUND OF INVENTION

In recent years, applications of thin film transistors (TFTs) in liquid crystal displays (LCDs) and organic light emitting diode (OLED) display devices have received widespread attention. Semiconductor materials used in an active layer of TFTs have undergone a transition from silicon-based to oxides, and performance of TFTs has also been continuously improved.

In the traditional process, the width-to-length ratio (W/L) of the channel of the active layer of the TFT is limited by a processing line width and wiring, and cannot be adjusted flexibly, that is, the adjustment of the characteristics of the TFT by the width-to-length ratio (W/L) is limited. Therefore, there is a need to alleviate this defect.

### SUMMARY OF INVENTION

### Technical Problem

An embodiment of the present invention provides an array substrate to solve the technical problem that a width-to-length ratio of a channel of an active layer of a TFT of an array substrate in the prior art is limited by a processing line width and wiring, and cannot be flexibly adjusted.

### Technical Solutions for Problem

### Technical Solutions

An embodiment of the present invention provides an array substrate including a substrate layer and at least one thin film transistor disposed on the substrate layer; wherein the thin film transistor includes an electrode layer including a first metal layer, a second metal layer, and a third metal layer which are stacked, wherein the second metal layer is insulated from the first metal layer and the third metal layer, respectively; a gate insulating layer disposed on a sidewall of the electrode layer; and an active layer disposed on a surface of the gate insulating layer away from the electrode layer, wherein a first end of the active layer is electrically connected to the first metal layer, and a second end of the active layer is electrically connected to the third metal layer; wherein, in a direction from the first metal layer to the third metal layer, the second metal layer includes at least two metal sub-layers which are stacked, and adjacent ones of the metal sub-layers are insulated from each other.

In the array substrate provided by an embodiment of the present invention, the active layer includes a first doped portion, a second doped portion, and a channel portion, and the channel portion is disposed between the first doped portion and the second doped portion; and wherein the first doped portion is electrically connected to the first metal layer, and the second doped portion is electrically connected to the third metal layer.

In the array substrate provided by an embodiment of the present invention, the first doped portion is disposed on a surface of the first metal layer facing the second metal layer, and the second doped portion is located a surface of the third metal layer away from the second metal layer.

In the array substrate provided by an embodiment of the present invention, a material of the active layer is metal oxide or amorphous silicon.

In the array substrate provided by an embodiment of the present invention, the thin film transistor further includes: a first insulating layer disposed between the second metal layer and the first metal layer; a second insulating layer disposed between the second metal layer and the third metal layer; and a third insulating layer disposed between adjacent ones of the metal sub-layers.

In the array substrate provided by an embodiment of the present invention, in the direction from the first metal layer to the third metal layer, a thickness of the first insulating layer and/or a thickness of the second insulating layer is greater than a thickness of the third insulating layer.

In the array substrate provided by an embodiment of the present invention, in the direction from the first metal layer to the third metal layer, the thickness of each of the first insulating layer, the second insulating layer, and the third insulating layer is greater than or equal to 500 angstroms and less than or equal to 4000 angstroms.

In the array substrate provided by an embodiment of the present invention, in the direction from the first metal layer to the third metal layer, the thickness of the third insulating layer is equal to the thickness of the first insulating layer; a ratio of the thickness of the third insulating layer to the thickness of the first insulating layer is a first ratio, a ratio of the thickness of the third insulating layer to the thickness of the second insulating layer is a second ratio, and the first ratio and/or the second ratio is greater than or equal to one-fifth and less than or equal to one-half.

In the array substrate provided by an embodiment of the present invention, the thin film transistor includes at least two of the third insulating layer, and in the direction from the first metal layer to the third metal layer, thicknesses of the at least two of the third insulating layer are equal.

In the array substrate provided by an embodiment of the present invention, in a direction from the active layer to the gate insulating layer, an included angle between the gate insulating layer and the first metal layer is greater than or equal to 60 degrees and less than or equal to 90 degrees.

In the array substrate provided by an embodiment of the present invention, the electrode layer includes a first groove, the first groove extends from the third metal layer to a surface of the first metal layer away from the substrate layer, and the gate insulating layer is disposed on an inner wall of the first groove.

In the array substrate provided by an embodiment of the present invention, in a top view of the thin film transistor, the first groove has a shape of a circle or a polygon.

In the array substrate provided by an embodiment of the present invention, the array substrate includes at least two thin film transistors, and the electrode layer further includes a second groove and at least two dividing grooves; wherein the second groove penetrates the active layer and the first metal layer, the second groove communicates with the first groove, an orthographic projection of the second groove on the substrate layer falls within an orthographic projection of the first groove on the substrate layer, and the second groove and the first groove are combined into a through groove; and wherein the dividing grooves penetrate the electrode layer, the gate insulating layer, and the active layer, the at least two dividing grooves communicate with the through groove, the at least two dividing grooves are defined around the through groove, and each of the dividing grooves is disposed between adjacent ones of the thin film transistors.

In the array substrate provided by an embodiment of the present invention, in a top view of the thin film transistors, areas of at least two of the thin film transistors are not equal.

In the array substrate provided by an embodiment of the present invention, in a top view of the thin film transistors, the second groove has a shape of a circle or a polygon.

In the array substrate provided by an embodiment of the present invention, in a top view of the thin film transistors, each of the dividing grooves has a shape of a rectangle or a trapezoid.

Another embodiment of the present invention further provides a method of manufacturing an array substrate, including: sequentially forming a first metal layer, a second metal layer, and a third metal layer that constitute an electrode layer on the substrate layer, wherein the second metal layer is respectively insulated from the first metal layer and the third metal layer, in a direction from the first metal layer to the third metal layer, the second metal layer includes at least two metal sub-layers which are stacked, and adjacent ones of the metal sub-layers are insulated from each other; forming a gate insulating layer on a sidewall of the electrode layer; and forming an active layer on a surface of the gate insulating layer away from the electrode layer, wherein a first end of the active layer is electrically connected to the first metal layer, and a second end of the active layer is electrically connected to the third metal layer.

In the method of manufacturing the array substrate provided by an embodiment of the present invention, the step of forming the gate insulating layer on the sidewall of the electrode layer includes: forming a first groove on the electrode layer, wherein the first groove extends from the third metal layer to a surface of the first metal layer away from the substrate layer; and forming a gate insulating layer on an inner wall of the first groove.

In the method of manufacturing the array substrate provided by an embodiment of the present invention, the method of manufacturing the array substrate further includes: forming a second groove on the electrode layer, wherein the second groove penetrates the active layer and the first metal layer, the second groove communicates with the first groove, an orthographic projection of the second groove on the substrate layer falls within an orthographic projection of the first groove on the substrate layer, and the second groove and the first groove are combined into a through groove; and forming at least two dividing grooves on the electrode layer, wherein the dividing grooves penetrate the electrode layer, the gate insulating layer, and the active layer, the at least two dividing grooves communicate with the through groove, the at least two dividing grooves are defined around the through groove, and a thin film transistor is formed between adjacent ones of the dividing grooves.

Still another embodiment of the present invention also provides a display panel including the above-mentioned array substrate.

### Beneficial Effect of the Invention

### Beneficial Effect

Beneficial effects: an embodiment of the present invention provides an array substrate, including a substrate layer and at least one thin film transistor disposed on the substrate layer; the thin film transistor includes an electrode layer, a gate insulating layer, and an active layer; the electrode layer includes a first metal layer, a second metal layer, and a third metal layer which are stacked, wherein the second metal layer is insulated from the first metal layer and the third metal layer, respectively; the gate insulating layer is provided on a sidewall of the electrode layer; the active layer is provided on a surface of the gate insulating layer away from the electrode layer, the first end of the active layer is electrically connected to the first metal layer, and a second end of the active layer is electrically connected to the third metal layer; and in a direction from the first metal layer to the third metal layer, the second metal layer includes at least two metal sub-layers which are stacked, and adjacent ones of the metal sub-layers are insulated from each other. In the present invention, the first metal layer, the second metal layer, and the third metal layer constituting the electrode layer are staked; a channel of the active layer is disposed on a sidewall of the electrode layer, and the second metal layer is divided into multiple metal sub-layers which are stacked. By adjusting thicknesses and a number of the metal sub-layers, a width-to-length ratio of the channel of the active layer can be adjusted to achieve the purpose of flexibly adjusting characteristics of the thin film transistor.

### Illustration of the Drawings

### BRIEF DESCRIPTION OF THE DRAWINGS

In order to more clearly illustrate the technical solutions of the embodiments of the application, the drawings illustrating the embodiments will be briefly described below.

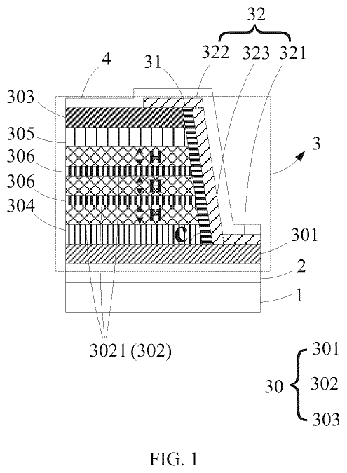

FIG. 1 is a schematic diagram of a basic structure of an array substrate provided by an embodiment of the present invention.

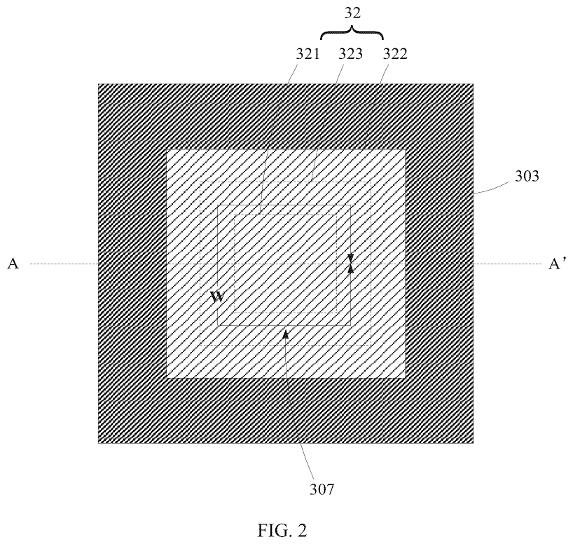

FIG. 2 is a top view of a thin film transistor provided by an embodiment of the present invention.

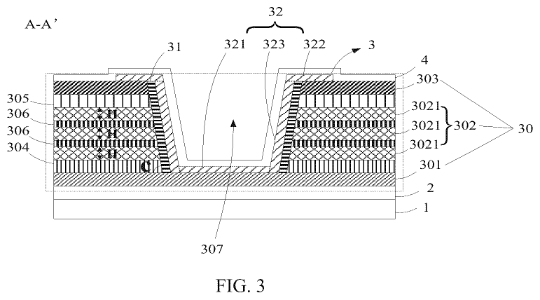

FIG. 3 is a cross-sectional view of another array substrate along a direction A-A′ in FIG. 2 provided by an embodiment of the present invention.

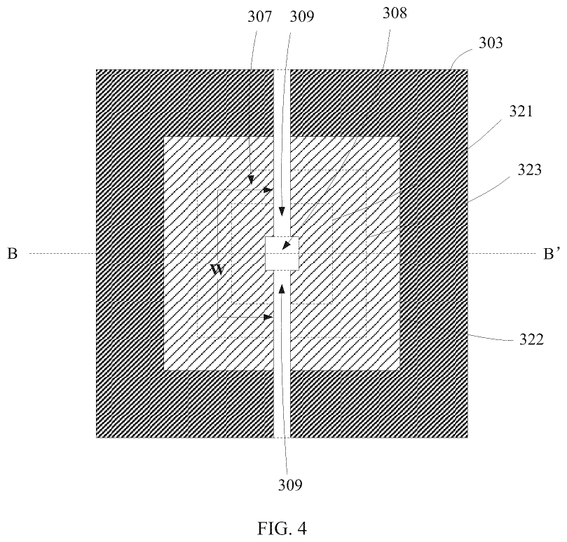

FIG. 4 is a top view of another thin film transistor provided by an embodiment of the present invention.

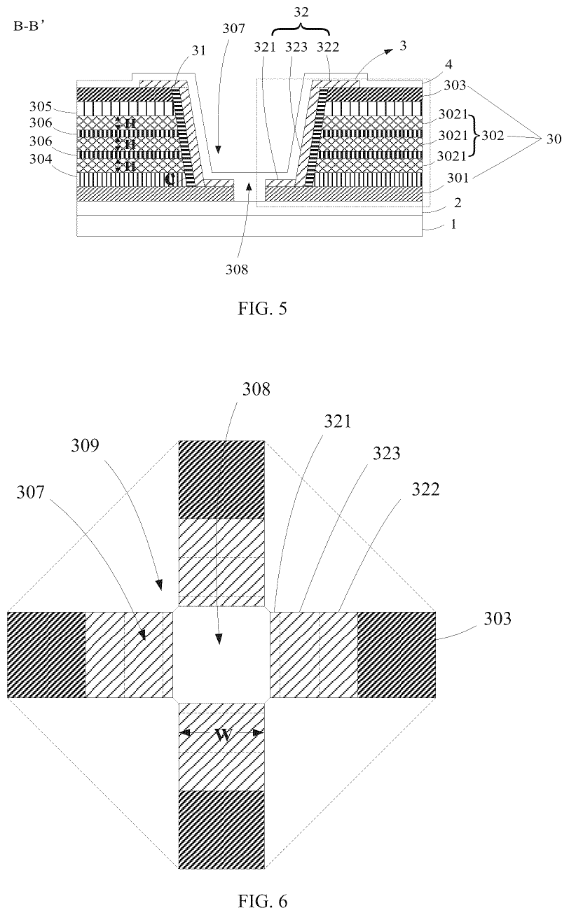

FIG. 5 is a cross-sectional view of another array substrate along a direction B-B′ in FIG. 4 according to an embodiment of the present invention.

FIG. 6 is a top view of a further thin film transistor provided by an embodiment of the present invention.

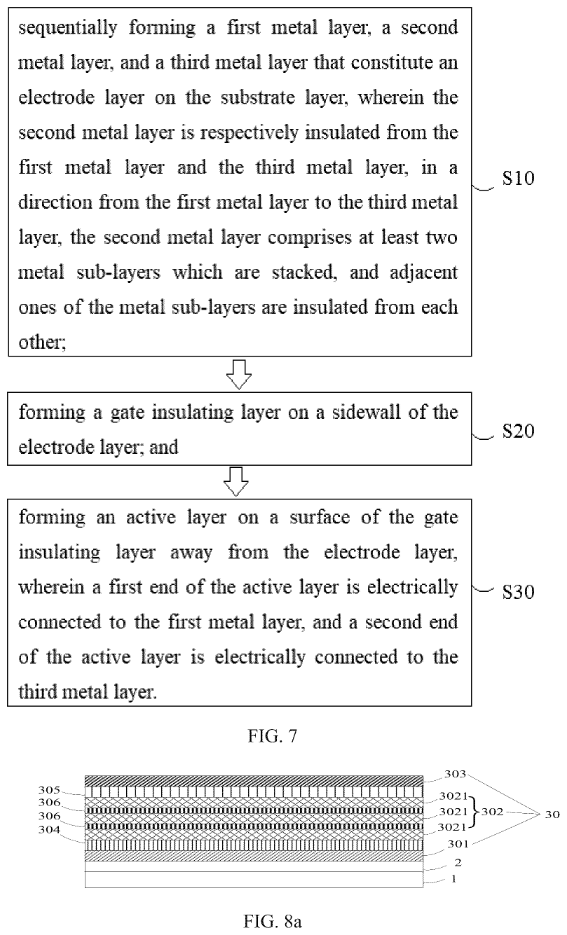

FIG. 7 is a flow chart of a method of manufacturing an array substrate provided by an embodiment of the present invention.

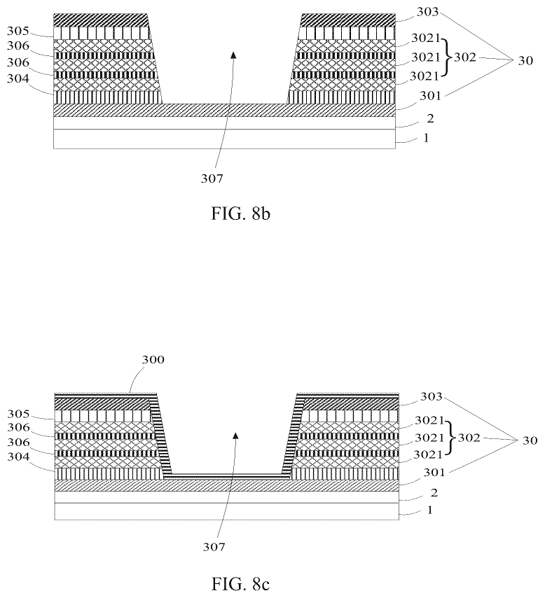

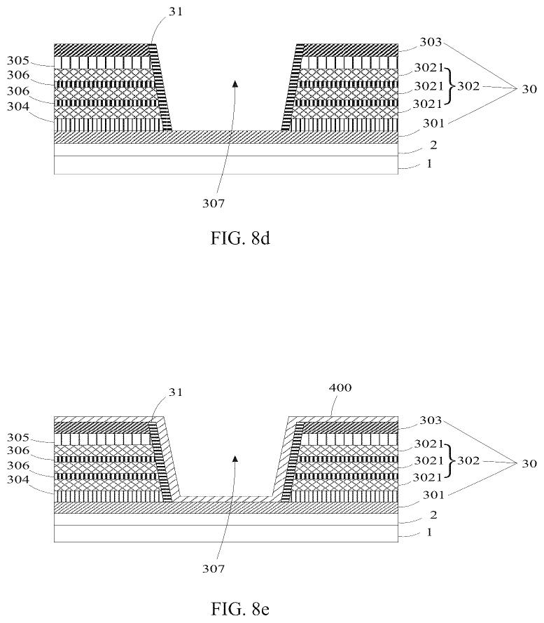

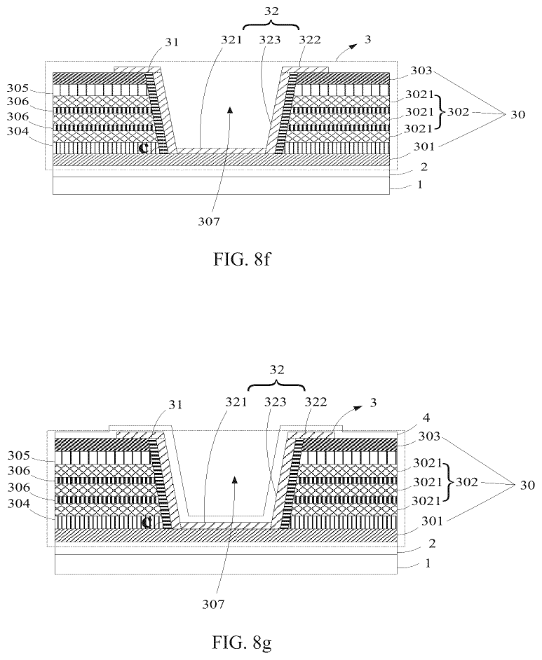

FIG. 8a to FIG. 8g are schematic diagrams of basic structures of components in a process flow of manufacturing the array substrate provided by an embodiment of the present invention.

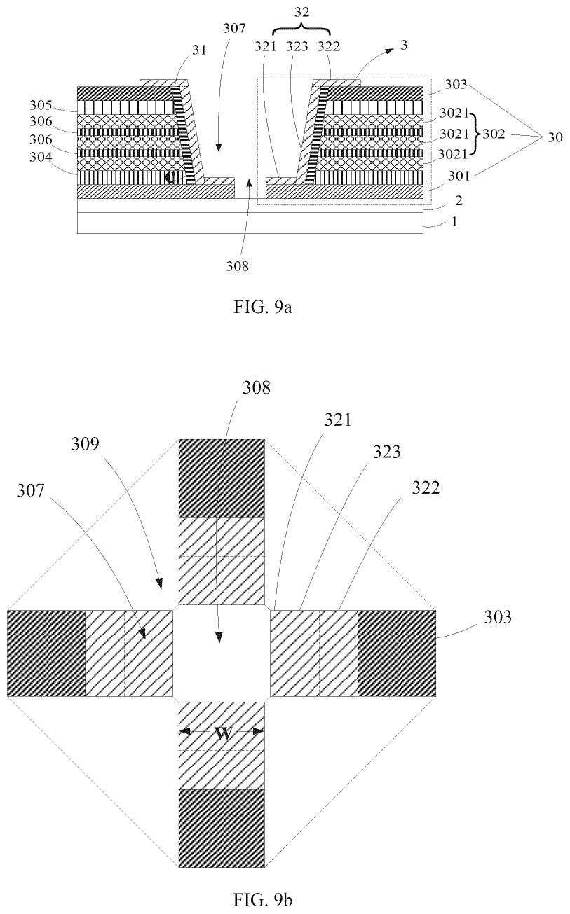

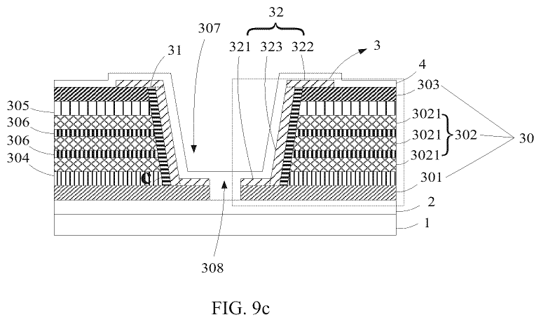

FIG. 9a to FIG. 9c are schematic diagrams of basic structures of components in another process flow of manufacturing the array substrate provided by an embodiment of the present invention.

### IMPLEMENTATIONS OF THE INVENTION

### Detailed Description of Embodiments

The technical solutions in the embodiments of the present application will be clearly and completely described in the following with reference to the accompanying drawings in the embodiments. In the drawings, for clarity and ease of understanding and description, the sizes and thicknesses of the components shown in the drawings are not drawn to scale.

As shown in FIG. 1, FIG. 1 is a schematic diagram of a basic structure of an array substrate provided by an embodiment of the present invention. The array substrate includes a substrate layer 1 and at least one thin film transistor 3 disposed on the substrate layer 1; wherein the thin film transistor 3 includes an electrode layer 30, a gate insulating layer 31, and an active layer 32; the electrode layer 30 includes a first metal layer 301, a second metal layer 302, and a third metal layer 303 that are stacked, and the second metal layer 302 is respectively insulated from the first metal layer 301 and the third metal layer 303; the gate insulating layer 31 is disposed on a sidewall of the electrode layer 30; the active layer 32 is disposed on a surface of the gate insulating layer 31 away from the electrode layer 30, and a first end of the active layer 32 is electrically connected to the first metal layer 301, and a second end of the active layer 32 is electrically connected to the third metal layer 303; in a direction from the first metal layer 301 to the third metal layer 303, the second metal layer 302 includes at least two metal sub-layers 3021 which are stacked, and adjacent ones of the metal sub-layers 3021 are insulated from each other.

It should be noted that the gate insulating layer 31 is disposed on the sidewall of the electrode layer 30, where the sidewall refers to a plane that forms a certain angle with a plane where the electrode layer 30 is located. It is appreciated with reference to FIG. 1, the plane where the electrode layer 30 is located is a horizontal plane, that is, a plane where the gate insulating layer 31 is located forms a certain angle with the horizontal plane.

It is appreciated that an embodiment of the present invention provides a thin film transistor 3 having a vertical channel structure, wherein the second metal layer 302 corresponds to the gate layer, while the first metal layer 301 and the third metal layer 303 correspond to a source layer and a drain layer. When the first metal layer 301 corresponds to the source layer, the third metal layer 303 corresponds to the drain layer; and when the first metal layer 301 corresponds to the drain layer, the third metal layer 303 corresponds to the source layer. The gate insulating layer 31 and the active layer 32 of the present invention are respectively formed on a sidewall of the electrode layer 30. The active layer 32 includes a first doped portion 321, a second doped portion 322, and a channel portion 323. The channel portion 323 is located between the first doped portion 321 and the second doped portion 322. The first doped portion 321 is electrically connected to the first metal layer 301; and the second doped portion 322 is electrically connected to the third metal layer 303. It can be seen from FIG. 1 that the channel portion 323 is substantially perpendicular to the electrode layer 30. A length of the channel portion 323 can be adjusted by adjusting thicknesses H and a number of the metal sub-layers 3021. FIG. 1 only takes the second metal layer 302 including three metal sub-layers 3021 as an example for illustration.

It should be noted that one of the characteristics of the thin film transistor 3 is a leakage current Ids. The leakage current Ids refers to: a current between the source and the drain (the first metal layer 301 and the third metal layer 303)) at a certain voltage when a voltage of the gate (i.e., the second metal layer 302) is 0. When the thin film transistor 3 works in a linear region, the leakage current Ids=μCi(W/L)[(Vgs−Vth) Vds−Vds2/2], where u is a mobility, Ci is a capacitance per unit area of the gate insulating layer 31, W is a width of the channel portion 323, L is a length of the channel portion 323, Vgs is a gate-source voltage, Vds is a drain-source voltage, and Vth is a threshold voltage. It can be concluded from the above formula that the larger the width-to-length ratio W/L is, the larger the leakage current Ids will be. Assuming that the width W of the channel portion 323 remains unchanged, in an embodiment of the present invention, the length L of the channel portion 323 can be adjusted by adjusting the thicknesses H and the number of the metal sub-layers 3021, that is, the length L of the active layer 32 can be adjusted. The width-to-length ratio (W/L) of the channel portion 323 achieves the purpose of flexibly adjusting characteristics of the thin film transistor 3.

It should be noted that the length L of the channel portion 323 is determined according to the thickness of the second metal layer 302 (that is, a cumulative sum of the thicknesses H of all the metal sub-layers 3021). Specifically, because the single-layered metal is easy to peel off when it is too thick, the thickness of the single-layered metal generally does not exceed 8000 angstroms, which limits the adjustment of the length L of the channel portion 323. In an embodiment of the present invention, by dividing the second metal layer 302 into a plurality of stacked metal sub-layers 3021, the thicknesses H of the multiple metal sub-layers 3021 can be accumulated. The number of the metal sub-layers 3021 can be flexibly adjusted to flexibly adjust the cumulative sum of the thicknesses H of the metal sub-layers 3021. That is, in the present invention, the width-to-length ratio (W/L) of the channel portion 323 of the active layer 32 can be flexibly adjusted by adjusting the thicknesses H and the number of the metal sub-layers 3021.

In an embodiment, a value of the width to length ratio (W/L) of the channel portion 323 is about 2. The value of (W/L) is varied according to a function of the thin film transistor 3. For example, values of (W/L) of a driving thin film transistor and a switching thin film transistor are different.

In one embodiment, the first doped portion 321 is disposed on a surface of the first metal layer 301 facing the second metal layer 302; the second doped portion 322 is disposed on a surface of the third metal layer 303 away from a surface of the second metal layer 302. That is, the first doped portion 321 is electrically connected to a portion of the first metal layer 301 that is not covered by the second metal layer 302 and the third metal layer 303. It is appreciated that in the process, an ion implanter is usually used to dope the semiconductor layer to form the first doped portion 321 and the second doped portion 322, and an un-doped portion of the semiconductor layer is the channel portion 323. Since a direction of the ion implantation is from the thin film transistor 3 to the substrate layer 1, that is, the side of the first metal layer 301 facing the second metal layer 302 and the side of the third metal layer 303 away from the second metal layer 302 may be doped. It should be noted that, in this embodiment, the first metal layer 301 is provided close to the substrate layer 1. In other embodiments, the third metal layer 303 may be provided close to the substrate layer 1. When the third metal layer 303 is disposed close to the substrate layer 1, the first doped portion 321 is disposed on the surface of the third metal layer 303 facing the second metal layer 302; and the second doped portion 322 is disposed on the surface of the first metal layer 301 away from the second metal layer 302.

In one embodiment, when the first metal layer 301 is disposed close to the substrate layer 1, the first metal layer 301 is the source layer, and the third metal layer 303 is the drain layer; when the third metal layer 303 is disposed close to the substrate layer 1, the third metal layer 303 is a source layer, and the first metal layer 301 is a drain layer. It is appreciated that in the thin film transistor 3, the drain layer needs to connect to an outside of the thin film transistor 3 through a via hole. In this embodiment, the drain layer is disposed on the side away from the substrate layer 1 to facilitate the connection.

In an embodiment, the material of the active layer 32 is metal oxide or amorphous silicon. It is appreciated that low-temperature polysilicon requires crystallization of amorphous silicon, and this process requires a flat surface. A part of the active layer 32 provided by the present invention is disposed on the first metal layer 301 and the third metal layer 303, and another part is disposed on the sidewall of the electrode layer 30, which is not a flat surface. As such, the active layer 32 provided by an embodiment of the present invention is not suitable to be prepared by using low-temperature polysilicon.

In an embodiment, the thin film transistor 3 further includes a first insulating layer 304, a second insulating layer 305, and a third insulating layer 306; the first insulating layer 304 is located between the second metal layer 302 and the first metal layer 301; the second insulating layer 305 is located between the second metal layer 302 and the third metal layer 303; and the third insulating layer 306 is located between adjacent ones of the metal sub-layers 3021. It is appreciated that, in this embodiment, the third insulating layer 306 is provided between adjacent ones of the metal sub-layers 3021, and a resistance of the third insulating layer 306 is connected in series with resistances of the multiple metal sub-layers 3021, which is equivalent to increasing an equivalent resistance between the first metal layer 301 and the third metal layer 303, so that the leakage current between the first metal layer 301 and the third metal layer 303 can be reduced. That is, in the present invention, by setting the second metal layer 302 as an alternating structure constituted by the metal sub-layer 3021 and the third insulating layer 306, adjacent ones of the metal sub-layers 3021 are spaced apart from each other by the third insulating layer 306, which can effectively reduce the leakage current of thin film transistors 3.

In an embodiment, a material of each of the first insulating layer 304, the second insulating layer 305, and the third insulating layer 306 is silicon dioxide or silicon nitride.

In an embodiment, in the direction from the first metal layer 301 to the third metal layer 303, a thickness of the first insulating layer 304 and/or a thickness of the second insulating layer 305 is greater than a thickness of the third insulating layer 306. It is appreciated that the first insulating layer 304 is located between the first metal layer 301 and the second metal layer 302, and the second insulating layer 305 is located between the second metal layer 302 and the third metal layer 303, that is, each of the first insulating layer 304 and the second insulating layer 305 is mainly used as a spacer layer to play a role of isolation. In the direction from the first metal layer 301 to the third metal layer 303, in this embodiment, the thickness of the third insulating layer 306 is set to be smaller than the thickness of the first insulating layer 304 and/or the thickness of the second insulating layer 305, to achieve an effect of reducing a stress between the multiple metal sub-layers 3021, thereby preventing an excessive stress from causing the metal sub-layer 3021 and the third insulating layer 306 to peel off.

In an embodiment, in the direction from the first metal layer 301 to the third metal layer 303, the thickness of each of the first insulating layer 304, the second insulating layer 305, and the third insulating layer 306 is greater than or equal to 500 angstroms and less than or equal to 4000 angstroms to prevent the first insulating layer 304, the second insulating layer 305, and the third insulating layer 306 from being too thick to make the channel portion 323 of the active layer 32 unable to conduct.

In an embodiment, in the direction from the first metal layer 301 to the third metal layer 303, a ratio of the thickness of the third insulating layer 306 to the thickness of the first insulating layer 304 is a first ratio, a ratio of the thickness of the third insulating layer 306 to the thickness of the second insulating layer 305 is a second ratio, and the first ratio and/or the second ratio is greater than or equal to one-fifth and less than or equal to one-half.

In an embodiment, the thin film transistor 3 includes at least two of the third insulating layer 306, and in the direction from the first metal layer 301 to the third metal layer 303, thicknesses of the at least two of the third insulating layer 306 are equal.

In an embodiment, the array substrate further includes a fourth insulating layer 2, and the fourth insulating layer 2 is located between the substrate layer 1 and the thin film transistor 3. A material of the fourth insulating layer 2 is silicon dioxide or silicon nitride. In the direction from the first metal layer 301 to the third metal layer 303, a thickness of the fourth insulating layer 2 is greater than or equal to 4000 angstroms and less than or equal to 8000 angstroms. The fourth insulating layer 2 is used as a barrier which can prevent alkaline ions in the substrate layer 1 from diffusing into the thin film transistor 3, and isolate water and oxygen in the air.

In an embodiment, the array substrate further includes a passivation layer 4, the passivation layer 4 is disposed on the fourth insulating layer 2, and the passivation layer 4 covers at least one of the thin film transistors 3.

In one embodiment, in the direction from the active layer 32 to the gate insulating layer 31, an included angle between the gate insulating layer 31 and the first metal layer 301 is greater than or equal to 60 degrees and less than or equal to 90 degrees. It is appreciated that since the active layer 32 is disposed on a surface of the gate insulating layer 31 away from the electrode layer 30, the plane where the channel portion 323 of the active layer 32 is located and the plane where the gate insulating layer 31 is located are parallel to each other. Therefore, an inclination angle of the channel portion 323 of the active layer 32 relative to the first metal layer 301 is equal to the included angle C. When the inclination angle of the channel portion 323 of the active layer 32 with respect to the first metal layer 301 is between 60 degrees and 90 degrees, during the ion implantation process, a doping amount of the channel portion 323 will be very small or even none, thus preventing the doped ions from impacting a current efficiency of the channel portion 323.

In an embodiment, when the inclination angle is 90 degrees, the active layer 32 may be formed by an atomic deposition method. It is appreciated that when the inclination angle is 90 degrees, the gate insulating layer 31 is perpendicular to the substrate layer 1, and the active layer 32 deposited by a common physical deposition method cannot cover the gate insulating layer 31. Atomic deposition is a chemical deposition method, which is a method of forming a deposited film by introducing alternating pulses of vapor precursors into a reactor to make the vapor precursors be chemically adsorbed and reacted on a deposited base. Therefore, even if the gate insulating layer 31 is perpendicular to the substrate layer 1, the chemical adsorption to the deposited base and surface reaction of the vapor precursors are not impacted, and the formed active layer 32 can cover the gate insulating layer 31.

Next, referring to FIGS. 2 and 3, FIG. 2 is a top view of a thin film transistor provided by an embodiment of the present invention, and FIG. 3 is a cross-sectional view of another array substrate along a direction A-A′ in FIG. 2 provided by an embodiment of the present invention. A difference from the array substrate provided in the embodiment of FIG. 1 is that, in the array substrate in this embodiment, the electrode layer 30 includes a first groove 307, and the first groove 307 extends from the third metal layer 303 to the surface of the first metal layer 301 away from the substrate layer 1, and the gate insulating layer 31 is disposed on an inner wall of the first groove 307. It is appreciated that, in this embodiment, the electrode layer 30 is etched to have the first groove 307 to expose the first metal layer 301 disposed close to the substrate layer 1; and the gate insulating layer 31 is disposed on the inner wall of the first groove 307, the active layer 32 is disposed on the surface of the gate insulating layer 31 away from the electrode layer 30, a first end of the active layer 32 is located at a bottom of the first groove 307 and is electrically connected to the exposed first metal layer 301, a second end of the active layer 32 is disposed on a surface of the third metal layer 303 away from the second metal layer 302 and is electrically connected to the third metal layer 303, and a channel between the first end and the second end is defined on a slope of the gate insulating layer 31 and is approximately perpendicular to the electrode layer 30, so that the thin film transistor 3 having a vertical channel structure is formed.

In an embodiment, in a top view of the thin film transistor 3, the first groove 307 has a shape of a circle or a polygon. Specifically, referring to FIG. 2, in this embodiment, the first groove 307 having a shape of a square in a top view is taken as an example for illustration. It is appreciated that, in FIGS. 2 and 3, a case that only one thin film transistor 3 is provided on the substrate layer 1 is taken as an example for illustration, and the width of the channel portion 323 of the thin film transistor 3 in FIGS. 2 and 3 corresponds to a circumference W of the inner wall of the groove 307 (as shown in FIG. 2). It should be noted that the thin film transistor 3 as described in FIG. 2 and FIG. 3 can be provided in plural on the substrate layer 1.

Next, a case that at least two thin film transistors 3 are provided on the substrate layer 1 is taken as an example for illustration. Referring to FIGS. 4 and 5, FIG. 4 is a top view of another thin film transistor provided by an embodiment of the present invention, and FIG. 5 is a cross-sectional view of another array substrate along a direction B-B′ in FIG. 4 according to an embodiment of the present invention. The array substrate includes a substrate layer 1 and at least one thin film transistor 3 disposed on the substrate layer 1; wherein the thin film transistor 3 includes an electrode layer 30, a gate insulating layer 31, and an active layer 32; the electrode layer 30 includes a first metal layer 301, a second metal layer 302, and a third metal layer 303 that are stacked; the second metal layer 302 is respectively insulated from the first metal layer 301 and the third metal layer 303; the gate insulating layer 31 is provided on a sidewall of the electrode layer 30; the gate insulating layer 31 is disposed on a sidewall of the electrode layer 30; the active layer 32 is disposed on a surface of the gate insulating layer 31 away from the electrode layer 30, and a first end of the active layer 32 is electrically connected to the first metal layer 301, and a second end of the active layer 32 is electrically connected to the third metal layer 303; in a direction from the first metal layer 301 to the third metal layer 303, the second metal layer 302 includes at least two metal sub-layers 3021 which are stacked, and adjacent ones of the metal sub-layers 3021 are insulated from each other.

In this embodiment, the electrode layer 30 includes a first groove 307, and the first groove 307 extends from the third metal layer 303 to the surface of the first metal layer 301 away from the substrate layer 1, and the gate insulating layer 31 is disposed on an inner wall of the first groove 307.

In an embodiment, in a top view of the thin film transistor 3, the first groove 307 has a shape of a circle or a polygon. Specifically, referring to FIG. 4, in this embodiment, the first groove 307 having a shape of a square in a top view is taken as an example for illustration.

In an embodiment, the array substrate includes at least two thin film transistors 3, wherein the electrode layer 30 further includes a second groove 308 and at least two dividing grooves 309; the second groove 308 penetrates the active layer 32 and the first metal layer 301, the second groove 308 communicates with the first groove 307, an orthographic projection of the second groove on the substrate layer falls within an orthographic projection of the first groove 308 on the substrate layer 1, and the second groove 308 and the first groove 307 are combined into a through groove; the dividing grooves 309 penetrate the electrode layer 30, the gate insulating layer 31, and the active layer 32, the at least two dividing grooves 309 communicate with the through groove, the at least two dividing grooves 309 are defined around the through groove, and each of the dividing grooves 309 is disposed between adjacent ones of the thin film transistors 3.

It is appreciated that a difference between this embodiment and the embodiment of FIGS. 2 and 3 is that, in this embodiment, the second groove 308 and at least two dividing grooves 309 are further introduced (only two divided grooves 309 are illustrated in FIG. 4 as an example). The second groove 308 is obtained by etching the first groove 307 downward to penetrate the active layer 32 and the first metal layer 301, and the second groove 308 and the first groove 307 are combined into a through groove, and the through groove penetrates the entire thin film transistor 3. In this embodiment, at least two dividing grooves 309 are provided, the at least two dividing grooves 309 communicate with the through groove, and the dividing groove 309 also penetrates through the entire thin film transistor 3. That is, the first groove 307, the second groove 308, and the at least two dividing grooves 309 collectively divide one thin film transistor into at least two thin film transistors.

In an embodiment, in a top view of the thin film transistor 3, areas of at least two thin film transistors 3 are not equal, which are not shown in this embodiment. It is appreciated that, in FIG. 4, a case that the electrode layer 30 includes two dividing grooves 309 is taken as an example for illustration. In FIG. 4, the two dividing grooves 309 are symmetrically distributed with respect to the through groove, so that the areas of the two divided thin film transistors in the top view are equal. However, in other embodiments, when the dividing grooves 309 are distributed asymmetrically, the thin film transistors with unequal areas can be divided. The thin film transistors with unequal areas have different channel widths W, and in this case, the channel length L of the thin film transistor is already fixed and unchanged, and different width-to-length ratios (W/L) can be formed by adjusting positions of the dividing groove 309 to meet requirements of different thin film transistors in a driving circuit.

In an embodiment, in a top view of the thin film transistor 3, the second groove 308 has a shape of a circle or a polygon. Specifically, referring to FIG. 4, in this embodiment, a case that the second groove 308 is square in a top view is taken as an example for illustration.

In an embodiment, in a top view of the thin film transistor 3, a shape of each of the dividing grooves 309 is rectangular or trapezoidal. Specifically, referring to FIG. 4, in this embodiment, the dividing groove 309 having a rectangular shape in a top view is taken as an example for illustration.

It should be noted that, in FIGS. 4 and 5, a case that at least two thin film transistors 3 are provided on the substrate layer 1 is taken as an example for illustration. In FIGS. 4 and 5, a sum of widths W of the channel portions 323 of the two thin film transistors 3 and widths of the two dividing grooves 309 corresponds to a circumference W of the inner wall of the groove 307. It should be noted that multiple sets of the two thin film transistors 3 as shown in FIG. 4 and FIG. 5 may be provided on the substrate layer 1.

Next, referring to FIG. 6, FIG. 6 is a top view of a further thin film transistor provided by an embodiment of the present invention, the electrode layer 30 (as shown in FIG. 5) further includes a second groove 308 and four dividing grooves 309; the second groove 308 penetrates the active layer 32 (as shown in FIG. 5) and the first metal layer 301 (as shown in FIG. 5); the second groove 308 communicates with the first groove 307; and an orthographic projection of the second groove 308 on the substrate layer 1 (as shown in FIG. 5) falls within an orthographic projection of the first groove 307 on the substrate layer 1, and the second groove 308 and the first groove 307 are combined into a through groove; the dividing groove 309 penetrates the electrode layer 30, the gate insulating layer 31 (as shown in FIG. 5), and the active layer 32; the four dividing grooves 309 communicate with the through groove; the four dividing grooves 309 are defined around the through groove; and each of the dividing grooves 309 is defined between adjacent ones of the thin film transistors.

It is appreciated that the difference between this embodiment and the embodiments of FIG. 4 and FIG. 5 is that the electrode layer 30 includes four dividing grooves 309, wherein the four dividing grooves 309 all communicate with the through groove, and each of the four dividing grooves 309 penetrates the entire thin film transistor, that is, the first groove 307, the second groove 308, and the four dividing grooves 309 collectively divide one thin film transistor into four thin film transistors.

In an embodiment, in a top view of the thin film transistor, the shape of each of the dividing grooves 309 is rectangular or trapezoidal. Specifically, referring to FIG. 6, in this embodiment, the dividing groove 309 having a shape of a trapezoid in the top view is taken as an example for illustration.

It should be noted that, in FIG. 6, only four thin film transistors are provided on the substrate layer 1 (as shown in FIG. 5) as an example for illustration. In FIG. 6, a sum of widths W of the channel portions 323 of the four thin film transistors and widths of the four dividing grooves 309 corresponds to a circumference of the inner wall of the groove 307. It should be noted that multiple sets of the four thin film transistors 3 as shown in FIG. 6 may be provided on the substrate layer 1.

It should be noted that, with the structure of the array substrate provided by an embodiment of the present invention, one thin film transistor can not only be divided into 2 or 4, but also 3, 5, and so on. The thin film transistors provided by the embodiments of the present invention do not individually correspond to sub-pixels, and may be connected in a certain driving connection manner to form a driving circuit.

Next, referring to FIG. 7, which is a flow chart of a method of manufacturing an array substrate provided by an embodiment of the present invention, the manufacturing method includes:

S10. sequentially forming a first metal layer, a second metal layer, and a third metal layer that constitute an electrode layer on the substrate layer, wherein the second metal layer is respectively insulated from the first metal layer and the third metal layer, in a direction from the first metal layer to the third metal layer, the second metal layer includes at least two metal sub-layers which are stacked, and adjacent ones of the metal sub-layers are insulated from each other;

S20, forming a gate insulating layer on a sidewall of the electrode layer; and

S30. forming an active layer on a surface of the gate insulating layer away from the electrode layer, wherein a first end of the active layer is electrically connected to the first metal layer, and a second end of the active layer is electrically connected to the third metal layer.

It is appreciated that in the present invention, by sequentially stacking the first metal layer, the second metal layer, and the third metal layer to form the electrode layer, and forming the gate insulating layer and the active layer on the sidewall of the electrode layer, the thin film transistor with a vertical channel structure is formed. In addition, the second metal layer is divided into a plurality of stacked metal sub-layers, and by adjusting thicknesses and a number of the metal sub-layers, a width-to-length ratio of the channel of the active layer can be adjusted to achieve the purpose of flexibly adjusting characteristics of the thin film transistor.

It should be noted that the second metal layer corresponds to the gate layer, and the first metal layer and the third metal layer correspond to the source layer and the drain layer. When the first metal layer corresponds to the source layer, the third metal layer corresponds to the drain layer; and when the first metal layer corresponds to the drain layer, the third metal layer corresponds to the source layer. The gate insulating layer and the active layer of the present invention are respectively formed on the sidewall of the electrode layer. The active layer includes a first doped portion, a second doped portion and a channel portion, and the channel portion is located between the first doped portion and the second doped portion. The first doped portion is electrically connected to the first metal layer; and the second doped portion is electrically connected to the third metal layer.

It should be noted that because the single-layered metal is easy to peel off when it is too thick, the thickness of the single-layered metal generally does not exceed 8000 angstrom. In an embodiment of the present invention, by dividing the second metal layer into a plurality of stacked metal sub-layers, the thicknesses of the multiple metal sub-layers can be accumulated, so that the number of the metal sub-layers can be flexibly adjusted to flexibly adjust the cumulative sum of the thicknesses of the metal sub-layers. That is, in the present invention, the width-to-length ratio (W/L) of the channel portion of the active layer can be flexibly adjusted by adjusting the thicknesses and the number of the metal sub-layers.

It should be noted that, in this embodiment, a case that the first metal layer is provided close to the substrate layer is taken as an example for illustration. In other embodiments, the third metal layer may also be provided close to the substrate layer. When the first metal layer is arranged close to the substrate layer, the first metal layer is the source layer, and the third metal layer is the drain layer; when the third metal layer is arranged close to the substrate layer, the third metal layer is the source layer, and the first metal layer is the drain layer. It is appreciated that in the thin film transistor, the drain layer needs to connect to an outside of the thin film transistor through a via hole. In this embodiment, the drain layer is disposed on the side away from the substrate layer to facilitate the connection.

In an embodiment, the material of the active layer is metal oxide or amorphous silicon. It is appreciated that low-temperature polysilicon requires crystallization of amorphous silicon, and this process requires a flat surface. A part of the active layer provided by the present invention is disposed on the first metal layer and the third metal layer, and another part is disposed on the sidewall of the electrode layer, which is not a flat surface. As such, the active layer provided by an embodiment of the present invention is not suitable for being prepared by using low-temperature polysilicon.

In an embodiment, the thin film transistor further includes a first insulating layer, a second insulating layer, and a third insulating layer; the first insulating layer is located between the second metal layer and the first metal layer; the second insulating layer is located between the second metal layer and the third metal layer; and the third insulating layer is located between adjacent ones of the metal sub-layers. It is appreciated that, in this embodiment, the third insulating layer is provided between adjacent ones of the metal sub-layers, and a resistance of the third insulating layer is connected in series with resistances of the multiple metal sub-layers, which is equivalent to increasing an equivalent resistance between the first metal layer and the third metal layer, so that the leakage current between the first metal layer and the third metal layer can be reduced. That is, in the present invention, by setting the second metal layer as an alternating structure constituted by the metal sub-layer and the third insulating layer, adjacent ones of the metal sub-layers are spaced apart from each other by the third insulating layer, which can effectively reduce the leakage current of thin film transistors.

In an embodiment, the material of each of the first insulating layer, the second insulating layer, and the third insulating layer is silicon dioxide or silicon nitride.

In an embodiment, in the direction from the first metal layer to the third metal layer, a thickness of the first insulating layer and/or a thickness of the second insulating layer is greater than a thickness of the third insulating layer. It is appreciated that the first insulating layer is located between the first metal layer and the second metal layer, and the second insulating layer is located between the second metal layer and the third metal layer, that is, each of the first insulating layer and the second insulating layer is mainly used as a spacer layer to play a role of isolation. In the direction from the first metal layer to the third metal layer, in this embodiment, the thickness of the third insulating layer is set to be smaller than the thickness of the first insulating layer and/or the thickness of the second insulating layer, to achieve an effect of reducing a stress between the multiple metal sub-layers, thereby preventing an excessive stress from causing the metal sub-layer and the third insulating layer to peel off.

In an embodiment, in the direction from the first metal layer to the third metal layer, the thickness of each of the first insulating layer, the second insulating layer, and the third insulating layer is greater than or equal to 500 angstroms and less than or equal to 4000 angstroms to prevent the first insulating layer, the second insulating layer, and the third insulating layer from being too thick to make the channel portion 323 of the active layer 32 unable to conduct.

In an embodiment, the array substrate further includes a fourth insulating layer, and the fourth insulating layer is located between the substrate layer and the thin film transistor. A material of the fourth insulating layer is silicon dioxide or silicon nitride. In the direction from the first metal layer to the third metal layer, a thickness of the fourth insulating layer is greater than or equal to 4000 angstroms and less than or equal to 8000 angstroms. The fourth insulating layer is used as a barrier which can prevent alkaline ions in the substrate layer from diffusing into the thin film transistor, and isolate water and oxygen in the air.

In an embodiment, the array substrate further includes a passivation layer, the passivation layer is disposed on the fourth insulating layer, and the passivation layer covers at least one of the thin film transistors.

In one embodiment, in the direction from the active layer to the gate insulating layer, an included angle between the gate insulating layer and the first metal layer is greater than or equal to 60 degrees and less than or equal to 90 degrees. It is appreciated that since the active layer is disposed on a surface of the gate insulating layer away from the electrode layer, the plane where the channel portion of the active layer is located and the plane where the gate insulating layer is located are parallel to each other. Therefore, an inclination angle of the channel portion of the active layer relative to the first metal layer is equal to the included angle. When the inclination angle of the channel portion of the active layer with respect to the first metal layer is between 60 degrees and 90 degrees, during the ion implantation process, a doping amount of the channel portion will be very small or even none, thus preventing the doped ions from impacting a current efficiency of the channel portion.

In an embodiment, when the inclination angle is 90 degrees, the active layer may be formed by an atomic deposition method. It is appreciated that when the inclination angle is 90 degrees, the gate insulating layer is perpendicular to the substrate layer, and the active layer deposited by a common physical deposition method cannot cover the gate insulating layer. Atomic deposition is a chemical deposition method, which is a method of forming a deposited film by introducing alternating pulses of vapor precursors into a reactor to make the vapor precursors be chemically adsorbed and reacted on a deposited base. Therefore, even if the gate insulating layer is perpendicular to the substrate layer, the chemical adsorption to the deposited base and surface reaction of the vapor precursors are not impacted, and the formed active layer can cover the gate insulating layer.

In one embodiment, the step of forming the gate insulating layer on the sidewall of the electrode layer includes: forming a first groove on the electrode layer, wherein the first groove extends from the third metal layer to a surface of the first metal layer away from the substrate layer; and forming a gate insulating layer on an inner wall of the first groove.

In an embodiment, the method of manufacturing the array substrate further includes: forming a second groove on the electrode layer, wherein the second groove penetrates the active layer and the first metal layer, the second groove communicates with the first groove, an orthographic projection of the second groove on the substrate layer falls within an orthographic projection of the first groove on the substrate layer, and the second groove and the first groove are combined into a through groove; and forming at least two dividing grooves on the electrode layer, wherein the dividing grooves penetrate the electrode layer, the gate insulating layer, and the active layer, the at least two dividing grooves communicate with the through groove, the at least two dividing grooves are defined around the through groove, and a thin film transistor is formed between adjacent ones of the dividing grooves.

Next, referring to FIGS. 8a to 8g, FIG. 8a to FIG. 8g are schematic diagrams of basic structures of components in a process flow of manufacturing the array substrate provided by an embodiment of the present invention. First, as shown in FIG. 8a, a fourth insulating layer 2, the first metal layer 301, the first insulating layer 304, the second metal layer 302, the second insulating layer 305, and the third metal layer 303 are sequentially deposited on the substrate layer 1, wherein the second metal layer 302 includes at least two metal sub-layers 3021 which are stacked in a direction from the metal layer 301 to the third metal layer 303 and insulated from each other (the second metal layer 302 including three metal sub-layers 3021 is illustrated in FIG. 8a as an example), and adjacent ones of the metal sub-layers 3021 are spaced apart from each other by a third insulating layer 306. The first metal layer 301, the second metal layer 302, and the third metal layer 303 constitute the electrode layer 30.

Next, as shown in FIG. 8b, a first groove 307 is formed on the electrode layer 30, and the first groove 307 extends from the third metal layer 303 to a surface of the first metal layer 301 away from the substrate layer 1.

Next, as shown in FIG. 8c, an insulating layer 300 is deposited on the electrode layer 30.

Next, as shown in FIG. 8d, the insulating layer 300 is patterned to form a gate insulating layer 31, and the gate insulating layer 31 is disposed on an inner wall of the first groove 307.

Next, as shown in FIG. 8e, a semiconductor layer 400 is deposited on the electrode layer 30.

Next, as shown in FIG. 8f, the semiconductor layer 400 is patterned to form an active layer 32. The active layer 32 is ion-doped to form a first doped portion 321, a second doped portion 322, and a channel portion 323, thus completing the thin film transistor 3. A channel portion 323 is located between the first doped portion 321 and the second doped portion 322. The first doped portion 321 is electrically connected to the first metal layer 301; and the second doped portion 322 is electrically connected to the third metal layer 303. In the direction from the active layer 32 to the gate insulating layer 31, an included angle between the gate insulating layer 31 and the first metal layer 301 is greater than or equal to 60 degrees and less than or equal to 90 degrees. It is appreciated that since the active layer 32 is disposed on a surface of the gate insulating layer 31 away from the electrode layer 30, the plane where the channel portion 323 of the active layer 32 is located and the plane where the gate insulating layer 31 is located are parallel to each other. Therefore, an inclination angle of the channel portion 323 of the active layer 32 relative to the first metal layer 301 is equal to the included angle C. When the inclination angle of the channel portion 323 of the active layer 32 with respect to the first metal layer 301 is between 60 degrees and 90 degrees, during the ion implantation process, a doping amount of the channel portion 323 will be very small or even none, thus preventing the doped ions from impacting a current efficiency of the channel portion 323.

Finally, as shown in FIG. 8g, a passivation layer 4 is formed on the fourth insulating layer 2, and the passivation layer 4 covers the thin film transistor layer 3.

It should be noted that the process flow of manufacturing the array substrate provided in this embodiment is described by taking only one thin film transistor 3 provided on the substrate layer 1 as an example.

In an embodiment, after patterning the semiconductor layer 400 to form the active layer 32, before ion doping the active layer 32, the method further includes the step of: forming a doped protection layer (not shown) on a surface of the active layer 32 away from the gate insulating layer 31 corresponding to an inner wall of the first groove 307. It is appreciated that, in this embodiment, a doping protection layer is first formed in a region corresponding to the channel portion 323, and then ion doping is performed, so that doping ions will not be implanted into the channel portion 323. The manufacturing method of this embodiment does not need to limit a size of the included angle C between the gate insulating layer 31 and the first metal layer 301.

Next, referring to FIGS. 9a to 9c, FIG. 9a to FIG. 9c are schematic diagrams of basic structures of components in another process flow of manufacturing the array substrate provided by an embodiment of the present invention. First, before performing the steps shown in FIG. 9a, the steps shown in FIG. 8a to FIG. 8f need to be performed first, that is, this embodiment continues to proceed on the basis of FIG. 8f.

As shown in FIG. 9a, the second groove 308 penetrates the active layer 32 and the first metal layer 301, the second groove 308 communicates with the first groove 307, an orthographic projection of the second groove on the substrate layer falls within an orthographic projection of the first groove 308 on the substrate layer 1, and the second groove 308 and the first groove 307 are combined into a through groove.

Next, as shown in FIG. 9b, four dividing grooves 309 are formed on the electrode layer 30, and the dividing grooves 309 penetrate the electrode layer 30, the gate insulating layer 31, and the active layer 32, The four dividing grooves 309 communicate with the through groove, the four dividing grooves 309 are arranged around the through groove, and a thin film transistor is formed between adjacent ones of the dividing grooves 309.

Finally, as shown in FIG. 9c, a passivation layer 4 is formed on the fourth insulating layer 2, and the passivation layer 4 covers the thin film transistor 3.

It should be noted that the process flow of manufacturing the array substrate provided in this embodiment only takes a case that one thin film transistor is divided into four thin film transistors as an example for illustration. However, the thin film transistor can also be divided into 2, 3, 5, etc.

An embodiment of the present invention also provides a display panel including the above-mentioned array substrate. The display panel provided by an embodiment of the present invention may be a liquid crystal display panel or an organic light emitting diode display panel.

An embodiment of the present invention also provides a display terminal including the above-mentioned display panel. The display terminal provided by an embodiment of the present invention may be a product or a component with a display function, such as a mobile phone, a tablet computer, a notebook computer, a television, a digital camera, a navigator, and the like.

In summary, an embodiment of the present invention provides an array substrate, including a substrate layer and at least one thin film transistor disposed on the substrate layer; the thin film transistor includes an electrode layer, a gate insulating layer, and an active layer; the electrode layer includes a first metal layer, a second metal layer, and a third metal layer which are stacked, wherein the second metal layer is insulated from the first metal layer and the third metal layer, respectively; the gate insulating layer is provided on a sidewall of the electrode layer; the active layer is provided on a surface of the gate insulating layer away from the electrode layer, the first end of the active layer is electrically connected to the first metal layer, and a second end of the active layer is electrically connected to the third metal layer; and in a direction from the first metal layer to the third metal layer, the second metal layer includes at least two metal sub-layers which are stacked, and adjacent ones of the metal sub-layers are insulated from each other. In the present invention, the first metal layer, the second metal layer, and the third metal layer constituting the electrode layer are staked; a channel of the active layer is disposed on a sidewall of the electrode layer, and the second metal layer is divided into multiple metal sub-layers which are stacked. By adjusting thicknesses and a number of the metal sub-layers, a width-to-length ratio of the channel of the active layer can be adjusted to achieve the purpose of flexibly adjusting characteristics of the thin film transistor, which solves the technical problem that a width-to-length ratio of a channel of an active layer of a TFT of an array substrate in the prior art is limited by a processing line width and wiring, and cannot be flexibly adjusted.

The array substrate, the manufacturing method thereof, and the display panel provided by the embodiments of the present invention have been described in detail above. It should be understood that the exemplary embodiments described herein should only be considered as descriptive, to help understand the method of the present invention and its core ideas, and not to limit the present invention.

What is claimed is:

1. An array substrate, comprising a substrate layer and at least one thin film transistor located on the substrate layer; wherein the thin film transistor comprises:
an electrode layer comprising a first metal layer, a second metal layer, and a third metal layer which are stacked, wherein the second metal layer is insulated from the first metal layer and the third metal layer, respectively;
a gate insulating layer disposed on a sidewall of the electrode layer; and
an active layer disposed on a surface of the gate insulating layer away from the electrode layer, wherein a first end of the active layer is electrically connected to the first metal layer, and a second end of the active layer is electrically connected to the third metal layer;
wherein, in a direction from the first metal layer to the third metal layer, the second metal layer comprises at least two metal sub-layers which are stacked, and adjacent ones of the metal sub-layers are insulated from each other.

2. The array substrate according to claim 1, wherein the active layer comprises a first doped portion, a second doped portion, and a channel portion, and the channel portion is disposed between the first doped portion and the second doped portion; and
wherein the first doped portion is electrically connected to the first metal layer, and the second doped portion is electrically connected to the third metal layer.

3. The array substrate according to claim 2, wherein the first doped portion is located on a surface of the first metal layer facing the second metal layer, and the second doped portion is located a surface of the third metal layer away from the second metal layer.

4. The array substrate according to claim 2, wherein a material of the active layer is metal oxide or amorphous silicon.

5. The array substrate according to claim 1, wherein the thin film transistor further comprises:
a first insulating layer disposed between the second metal layer and the first metal layer;
a second insulating layer disposed between the second metal layer and the third metal layer; and
a third insulating layer disposed between adjacent ones of the metal sub-layers.

6. The array substrate according to claim 5, wherein in the direction from the first metal layer to the third metal layer, a thickness of the first insulating layer and/or a thickness of the second insulating layer is greater than a thickness of the third insulating layer.

7. The array substrate according to claim 6, wherein in the direction from the first metal layer to the third metal layer, the thickness of each of the first insulating layer, the second insulating layer, and the third insulating layer is greater than or equal to 500 angstroms and less than or equal to 4000 angstroms.

8. The array substrate according to claim 7, wherein in the direction from the first metal layer to the third metal layer, the thickness of the third insulating layer is equal to the thickness of the first insulating layer; a ratio of the thickness of the third insulating layer to the thickness of the first insulating layer is a first ratio, a ratio of the thickness of the third insulating layer to the thickness of the second insulating layer is a second ratio, and the first ratio and/or the second ratio is greater than or equal to one-fifth and less than or equal to one-half.

9. The array substrate according to claim 5, wherein the thin film transistor comprises at least two of the third insulating layer, and in the direction from the first metal layer to the third metal layer, thicknesses of the at least two of the third insulating layer are equal.

10. The array substrate according to claim 1, wherein in a direction from the active layer to the gate insulating layer, an included angle between the gate insulating layer and the first metal layer is greater than or equal to 60 degrees and less than or equal to 90 degrees.

11. The array substrate according to claim 1, wherein the electrode layer comprises a first groove, the first groove extends from the third metal layer to a surface of the first metal layer away from the substrate layer, and the gate insulating layer is located on an inner wall of the first groove.

12. The array substrate according to claim 11, wherein in a top view of the thin film transistor, the first groove has a shape of a circle or a polygon.

13. The array substrate according to claim 11, wherein the array substrate comprises at least two thin film transistors, and the electrode layer further comprises a second groove and at least two dividing grooves;
wherein the second groove penetrates the active layer and the first metal layer, the second groove communicates with the first groove, an orthographic projection of the second groove on the substrate layer falls within an orthographic projection of the first groove on the substrate layer, and the second groove and the first groove are combined into a through groove; and
wherein the dividing grooves penetrate the electrode layer, the gate insulating layer, and the active layer, the at least two dividing grooves communicate with the through groove, the at least two dividing grooves are defined around the through groove, and each of the dividing grooves is disposed between adjacent ones of the thin film transistors.

14. The array substrate according to claim 13, wherein in a top view of the thin film transistors, areas of at least two of the thin film transistors are not equal.

15. The array substrate according to claim 13, wherein in a top view of the thin film transistors, the second groove has a shape of a circle or a polygon.

16. The array substrate according to claim 13, wherein in a top view of the thin film transistors, each of the dividing grooves has a shape of a rectangle or a trapezoid.

17. A method of manufacturing an array substrate, comprising:
sequentially forming a first metal layer, a second metal layer, and a third metal layer that constitute an electrode layer on the substrate layer, wherein the second metal layer is respectively insulated from the first metal layer and the third metal layer, in a direction from the first metal layer to the third metal layer, the second metal layer comprises at least two metal sub-layers which are stacked, and adjacent ones of the metal sub-layers are insulated from each other;
forming a gate insulating layer on a sidewall of the electrode layer; and
forming an active layer on a surface of the gate insulating layer away from the electrode layer, wherein a first end of the active layer is electrically connected to the first metal layer, and a second end of the active layer is electrically connected to the third metal layer.

18. The method of manufacturing the array substrate according to claim 17, wherein the step of forming the gate insulating layer on the sidewall of the electrode layer comprises:
forming a first groove on the electrode layer, wherein the first groove extends from the third metal layer to a surface of the first metal layer away from the substrate layer; and
forming a gate insulating layer on an inner wall of the first groove.

19. The method of manufacturing the array substrate according to claim 18, wherein the method of manufacturing the array substrate further comprises:
forming a second groove on the electrode layer, wherein the second groove penetrates the active layer and the first metal layer, the second groove communicates with the first groove, an orthographic projection of the second groove on the substrate layer falls within an orthographic projection of the first groove on the substrate layer, and the second groove and the first groove are combined into a through groove; and
forming at least two dividing grooves on the electrode layer,
wherein the dividing grooves penetrate the electrode layer, the gate insulating layer, and the active layer, the at least two dividing grooves communicate with the through groove, the at least two dividing grooves are defined around the through groove, and a thin film transistor is formed between adjacent ones of the dividing grooves.

20. A display panel, comprising an array substrate, the array substrate comprising a substrate layer and at least one thin film transistor located on the substrate layer; wherein the thin film transistor comprises:
an electrode layer comprising a first metal layer, a second metal layer, and a third metal layer which are stacked, wherein the second metal layer is insulated from the first metal layer and the third metal layer, respectively;
a gate insulating layer disposed on a sidewall of the electrode layer; and
an active layer disposed on a surface of the gate insulating layer away from the electrode layer, wherein a first end of the active layer is electrically connected to the first metal layer, and a second end of the active layer is electrically connected to the third metal layer;
wherein, in a direction from the first metal layer to the third metal layer, the second metal layer comprises at least two metal sub-layers which are stacked, and adjacent ones of the metal sub-layers are insulated from each other.
